(19) United States
(12) Patent Application Publication
(10) Pub. No.: US 2026/0073986 A1
(43) Pub. Date: Mar. 12, 2026

(54) Memory Arrays And Methods Used In Forming Memory Circuitry

(71) Applicant: Micron Technology, Inc., Boise, ID (US)

(72) Inventors: Nicolo' Gravellini, Milano (IT); Lorenzo Pedrazzetti, Soncino (IT); Paolo Tessariol, Arcore (IT)

(73) Assignee: Micron Technology, Inc., Boise, ID (US)

(21) Appl. No.: 19/309,031

(22) Filed: Aug. 25, 2025

Related U.S. Application Data
(60) Provisional application No. 63/693,837, filed on Sep. 12, 2024.

(51) Int. Cl. G11C 16/04; H10B 41/10; H10B 41/27; H10B 41/40; H10B 43/10; H10B 43/27; H10B 43/40

(52) U.S. Cl. CPC G11C 16/0483; H10B 41/10; H10B 41/27; H10B 41/40; H10B 43/10; H10B 43/27; H10B 43/40

(57) ABSTRACT

A memory array comprises a stack comprising vertically-alternating insulative tiers and conductive tiers. Channel-material strings extend through the insulative tiers and the conductive tiers and are arrayed in sets that are spaced from one another in horizontal X and Y directions. The channel-material strings in individual of the sets are arrayed in groups that are spaced from one another in the Y direction. Individual of the groups comprise multiple rows of the channel-material strings that are spaced from one another in the Y direction. Y-direction distance between immediately-adjacent of the groups is greater than Y-direction distance between immediately-adjacent of the rows within the individual groups. The stack comprises memory blocks that are spaced from one another in the Y direction. Immediately-adjacent of the memory blocks have a wall there-between that extends through the stack and is horizontally elongated in the X direction through multiple of the sets and through space that is between the individual groups in the individual sets. Methods are disclosed.

### TECHNICAL FIELD

Embodiments disclosed herein pertain to memory arrays and to methods used in forming memory circuitry.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The sense lines may conductively interconnect memory cells along columns of the array, and the access lines may conductively interconnect memory cells along rows of the array. Each memory cell may be uniquely addressed through the combination of a sense line and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

A field effect transistor is one type of electronic component that may be used in a memory cell. These transistors comprise a pair of conductive source/drain regions having a semiconductive channel region there-between. A conductive gate is adjacent the channel region and separated there-from by a thin gate insulator. Application of a suitable voltage to the gate allows current to flow from one of the source/drain regions to the other through the channel region. When the voltage is removed from the gate, current is largely prevented from flowing through the channel region. Field effect transistors may also include additional structure, for example a reversibly programmable charge-storage region as part of the gate construction between the gate insulator and the conductive gate.

Flash memory is one type of memory and has numerous uses in modern computers and devices. For instance, modern personal computers may have BIOS stored on a flash memory chip. As another example, it is becoming increasingly common for computers and other devices to utilize flash memory in solid state drives to replace conventional hard drives. As yet another example, flash memory is popular in wireless electronic devices because it enables manufacturers to support new communication protocols as they become standardized, and to provide the ability to remotely upgrade the devices for enhanced features.

NAND may be a basic architecture of integrated flash memory. A NAND cell unit comprises at least one selecting device coupled in series to a serial combination of memory cells (with the serial combination commonly being referred to as a NAND string). NAND architecture may be configured in a three-dimensional arrangement comprising vertically-stacked memory cells individually comprising a reversibly programmable vertical transistor. Control or other circuitry may be formed below the vertically-stacked memory cells. Other volatile or non-volatile memory array architectures may also comprise vertically-stacked memory cells that individually comprise a transistor.

Memory arrays may be arranged in memory pages, memory blocks and partial blocks (e.g., sub-blocks), and memory planes, for example as shown and described in any of U.S. Patent Application Publication Nos. 2015/0228651, 2016/0267984, and 2017/0140833. The memory blocks may at least in part define longitudinal outlines of individual wordlines in individual wordline tiers of vertically-stacked memory cells. Connections to these wordlines may occur in a so-called “stair-step structure” at an end or edge of an array of the vertically-stacked memory cells. The stair-step structure includes individual “stairs” (alternately termed “steps” or “stair-steps”) that define contact regions of the individual wordlines upon which elevationally-extending conductive vias contact to provide electrical access to the wordlines.

### BRIEF DESCRIPTION OF THE DRAWINGS

FIG. 1-7 are diagrammatic sectional or plan views of a portion of memory circuitry in process in accordance with embodiments of the invention.

FIGS. 8-41 are diagrammatic sectional, expanded, enlarged, and/or partial views of the construction of FIGS. 1-7 and/or of alternate embodiments.

### DETAILED DESCRIPTION OF EXAMPLE EMBODIMENTS

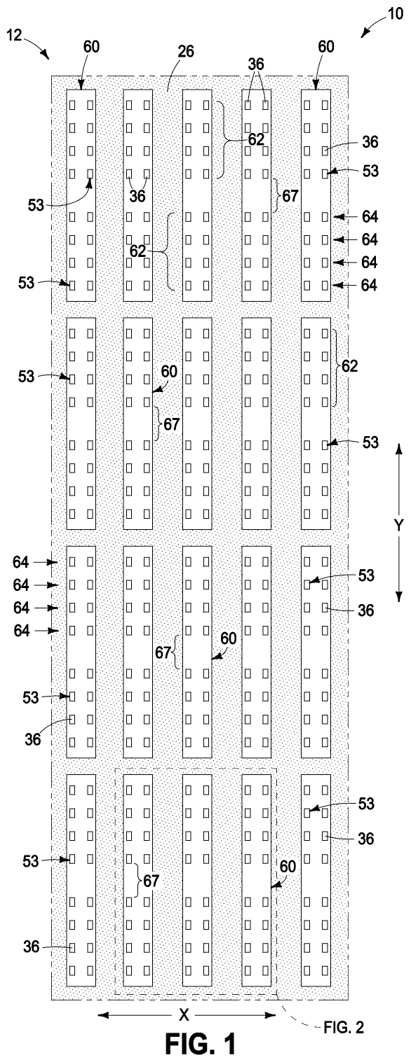

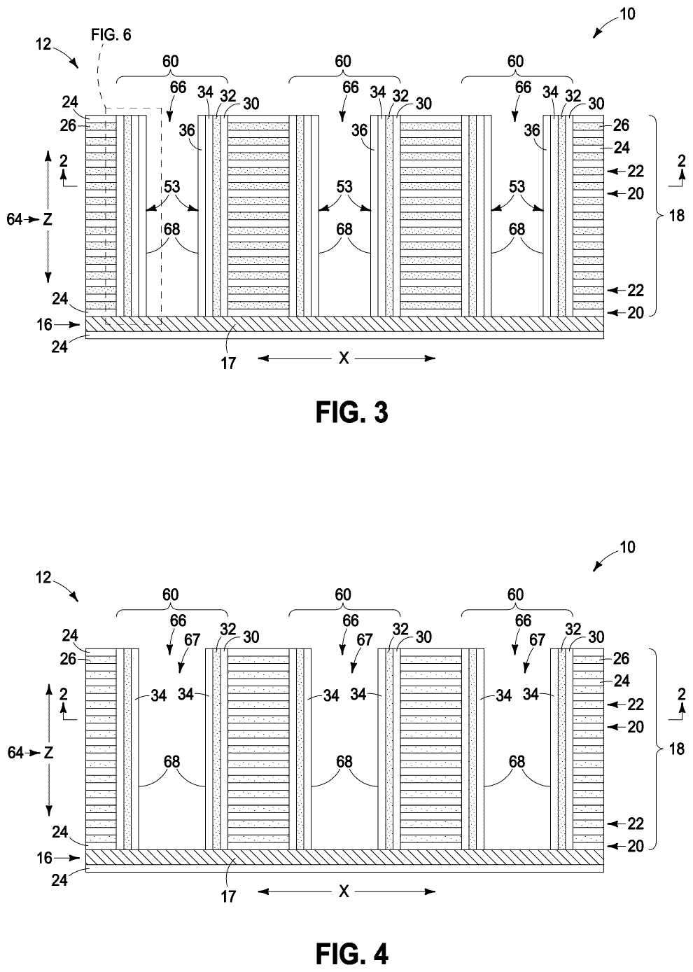

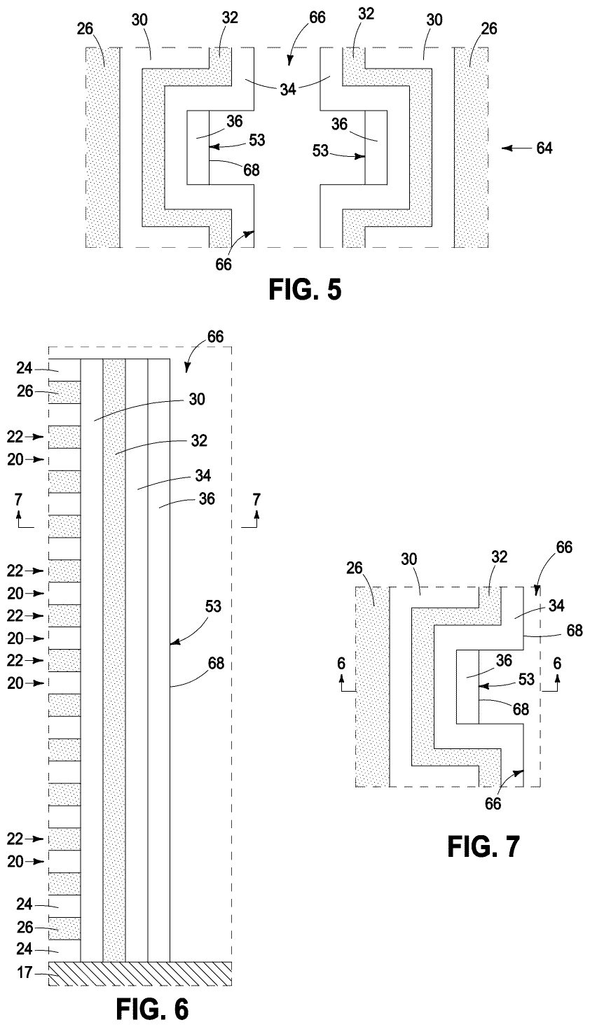

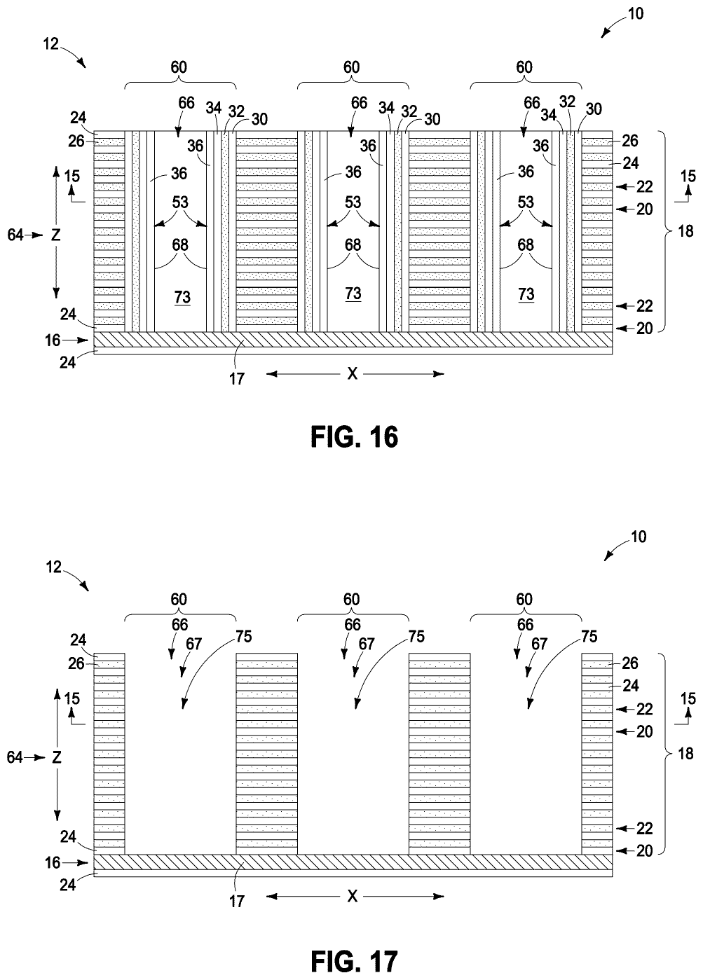

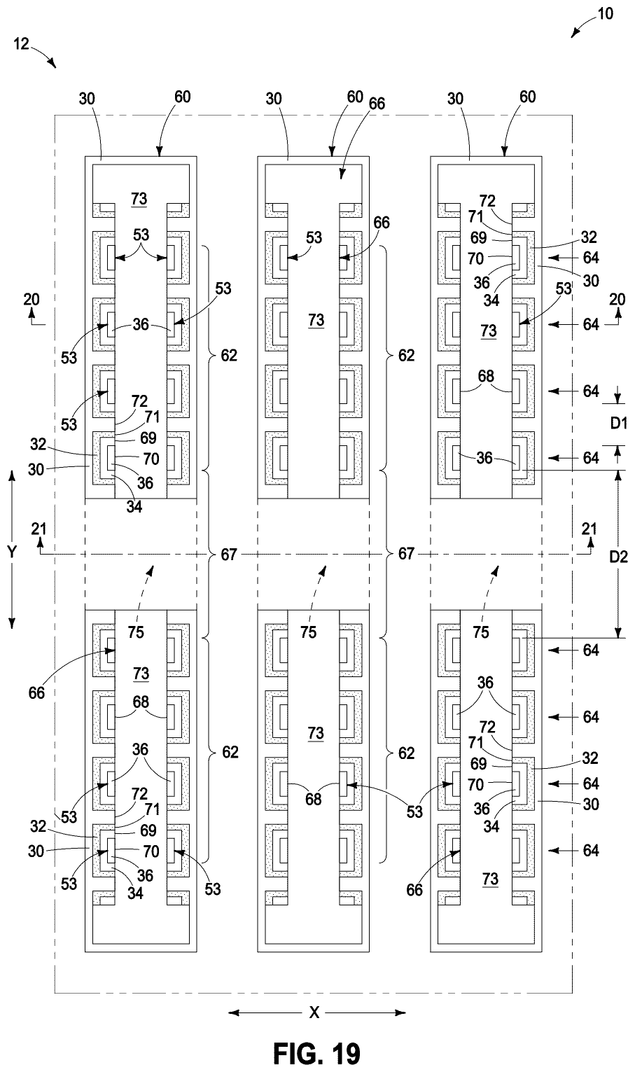

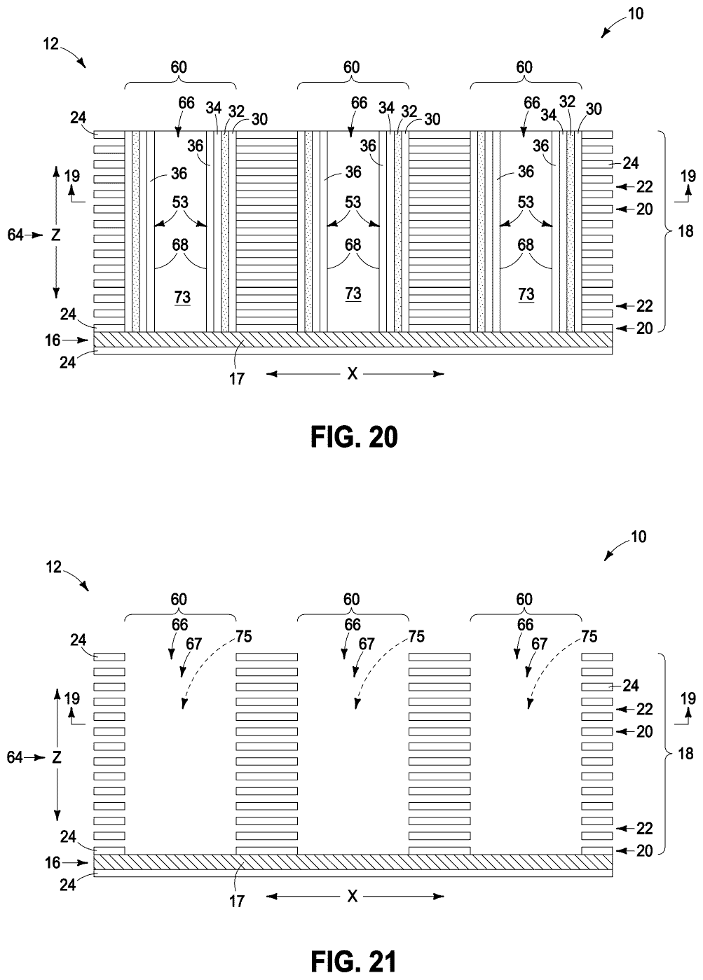

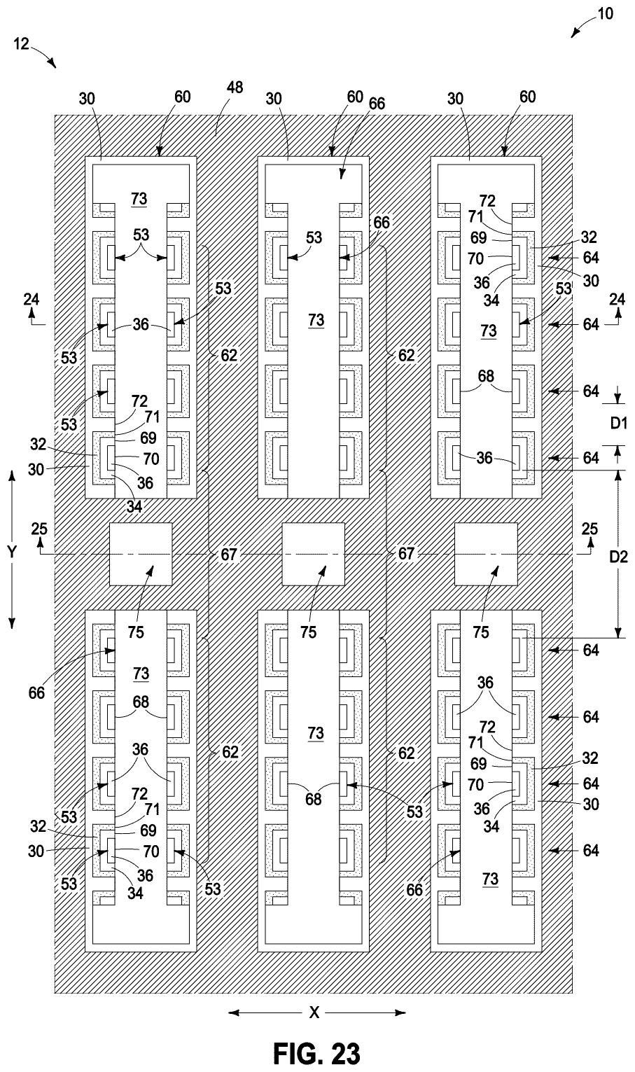

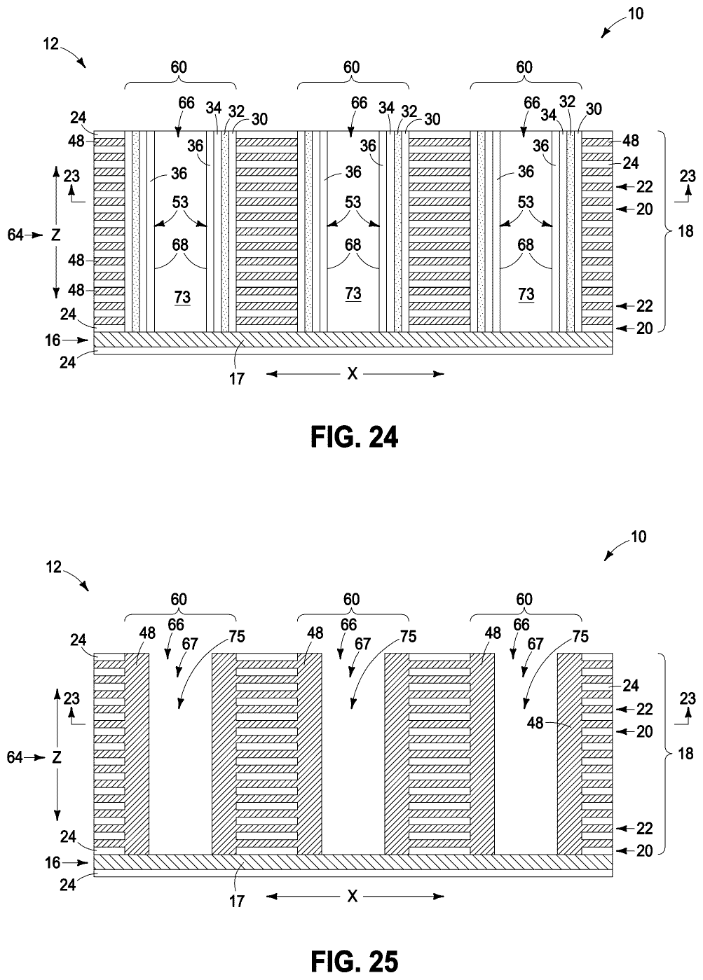

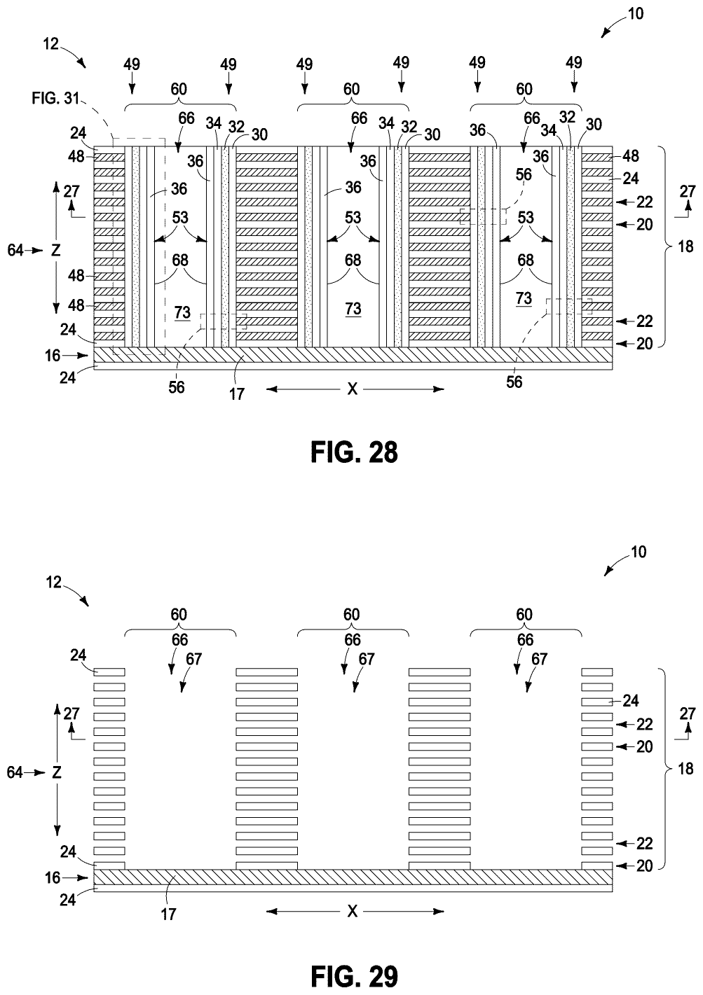

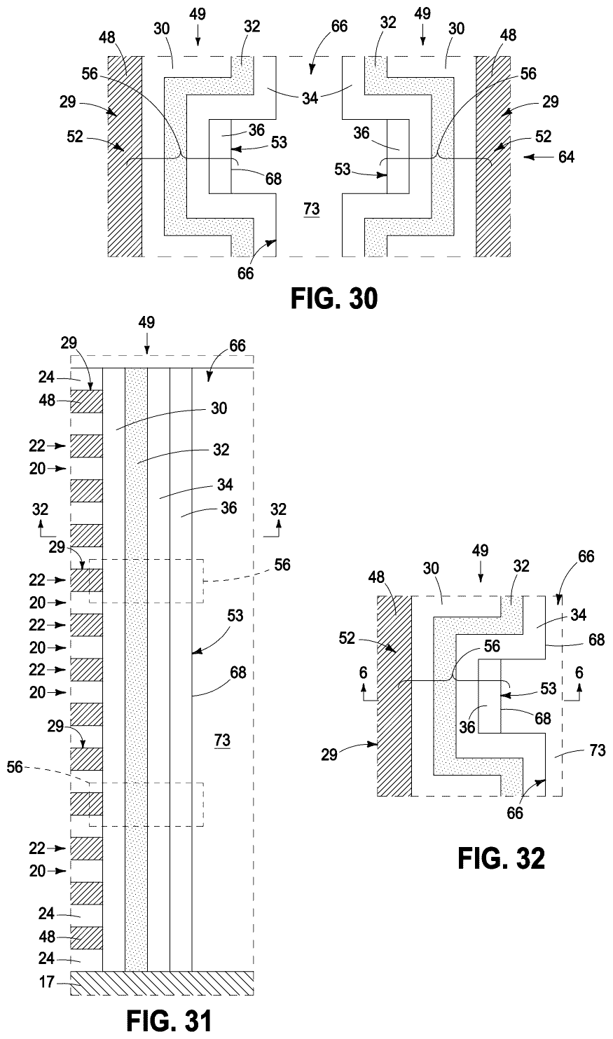

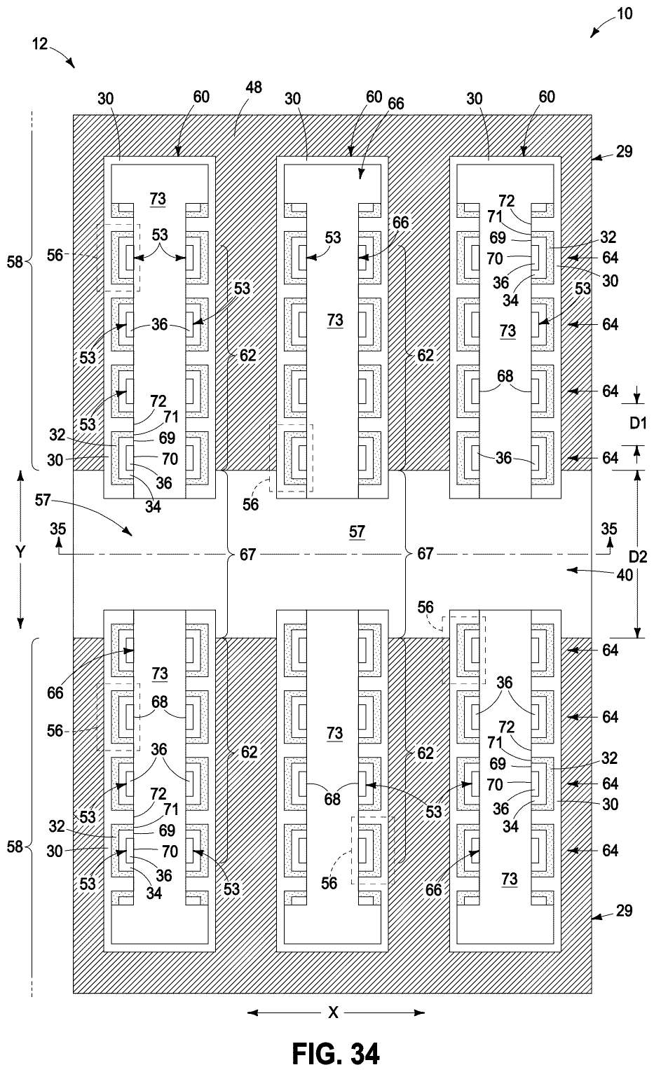

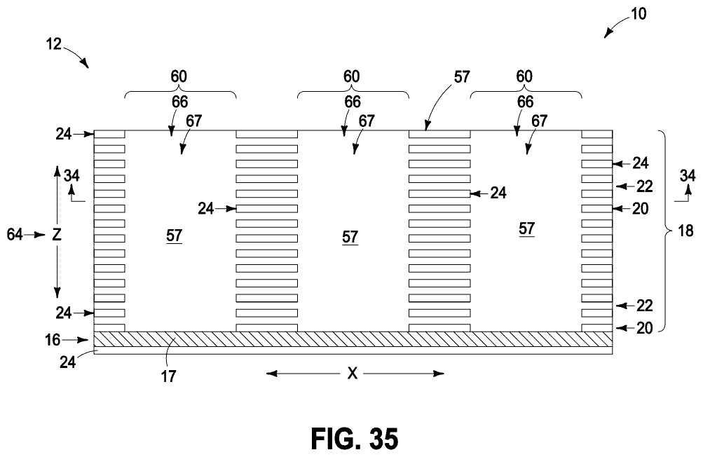

Embodiments of the invention encompass methods used in forming integrated circuitry, for example memory circuitry comprising a memory array, for example an array of NAND or other memory cells (e.g., integrated-circuitry components) that may have at least some peripheral control circuitry under the array (e.g., CMOS-under-array). Alternately, and by way of examples only, peripheral control circuitry may be above the array or to a side of the array. Embodiments of the invention encompass so-called “gate-last” or “replacement-gate” processing, so-called “gate-first” processing, and other processing whether existing or future-developed independent of when transistor gates are formed. Embodiments of the invention also encompass integrated circuitry such as that comprising a memory array comprising strings of memory cells (e.g., NAND architecture) independent of method of manufacture. Some example embodiments are described with reference to FIGS. 1-41.

FIGS. 1-7 show an example construction 10 with an array 12 in which strings of memory cells will be formed. Example construction 10 may include a lowest base substrate (not shown) having any one or more of conductive/conductor/conducting, semiconductive/semiconductor/semiconducting, or insulative/insulator/insulating (i.e., electrically herein) materials. Various materials may be formed above the base substrate. Materials may be aside, elevationally inward, or elevationally outward of the FIGS. 1-7—depicted materials. For example, other partially or wholly fabricated components of integrated circuitry may be provided somewhere above, about, or within a base substrate. Control and/or other peripheral circuitry for operating components within an array (e.g., array 12) of elevationally-extending strings of memory cells may also be fabricated and may or may not be wholly or partially within an array or sub-array. Further, multiple sub-arrays may also be fabricated and operated independently, in tandem, or otherwise relative one another. In this document, a “sub-array” may also be considered as an array.

Example construction 10 comprises a conductor tier 16 comprising conductor material 17 (e.g., WSiₓ under conductively-doped polysilicon). Conductor tier 16 may comprise part of control circuitry (e.g., peripheral-under-array circuitry and/or a common source line or plate) used to control read and write access to the transistors and/or memory cells in array 12. Construction 10 comprises a stack 18 comprising vertically-alternating (in a Z direction) first/conductive tiers 22 and second/insulative tiers 20. Example thickness for each of tiers 20 and 22 is 20 to 60 nanometers. The example uppermost tier 20 may be thicker/thickest compared to one or more other tiers 20 and/or 22. Only a small number of tiers 20 and 22 is shown, with more likely stack 18 comprising dozens, a hundred or more, etc. of tiers 20 and 22. Other circuitry that may or may not be part of peripheral and/or control circuitry may be below or above stack 18. For example, multiple vertically-alternating tiers of conductive material and insulative material of such circuitry may be below a lowest of the conductive tiers 22 and/or above an uppermost of the conductive tiers 22. For example, one or more select-gate tiers (not shown) may be part of the bottom of stack 18. Conductive tiers 22 may not be conductive at this point of processing, for example if “gate-last”/“replacement gate”, and insulative tiers 20 may not be insulative at this point of processing (but will be at least in a finished-circuitry construction). Regardless, in some embodiments conductive tiers 22 are referred to as first tiers 22 and insulative tiers 20 are referred to as second tiers 20, and which are of different compositions relative one another. Example insulative/second tiers 20 comprise insulative material 24 (e.g., silicon dioxide and/or other material that may be of one or more composition(s)). Example conductive/first tiers 22 comprise sacrificial material 26 (e.g., silicon nitride) in the example gate-last processing. Such would comprise conductive material (not shown) in so-called gate-first processing.

Channel-material strings 53 extend through first tiers 22 and second tiers 20. Channel-material strings 53 are arrayed in sets 60 that are spaced from one another in horizontal X and Y directions that are orthogonal relative one another. Channel-material strings 53 in individual of sets 60 are arrayed in groups 62 that are spaced from one another in the Y direction. Individual of groups 62 comprise multiple rows 64 of channel-material strings 53 and that are spaced from one another in the Y direction. More or fewer sets, groups, and/or rows may be in construction 10 (not shown). Y-direction distance (D2) between immediately-adjacent of groups 62 is greater than Y-direction distance (D1) between immediately-adjacent of rows 64 within individual groups 62 (no groups or rows being between those that are, respectively, immediately adjacent one another). A space 67 is between groups 62 that are immediately adjacent one another in the Y direction.

Example channel-material strings 53 extend to conductor tier 16. In some embodiments, channel-material strings 53 may go into conductor material 17 of conductor tier 16 as shown or may stop there-atop (not shown). Alternately, as an example, channel-material strings 53 may stop atop or within the lowest insulative tier 20. A reason for extending channel-material strings 53 at least to conductor material 17 of conductor tier 16 is to assure direct electrical coupling of channel material of channel-material strings 53 to conductor tier 16 without using alternative processing and structure to do so when such a connection is desired and/or to provide an anchoring effect to channel-material strings 53. Etch-stop material (not shown) may be within or atop conductor material 17 of conductor tier 16 to facilitate processing in forming of channel-material strings 53. Such etch-stop material may be sacrificial or non-sacrificial. By way of example, yet in some embodiments, rows 64 individually have two and only two of channel-material strings 53 and there are two and only two groups 62 in individual sets 60. Alternate arrangements and constructions may be used.

Channel-material strings 53 comprise channel material 36 that may directly electrically couple with conductor material 17 in conductor tier 16. Individual memory cells of the example memory array being formed may comprise a gate region (e.g., a control-gate region) and a memory structure laterally between the gate region and the channel material. In one such embodiment, the memory structure is formed to comprise a charge-blocking region, storage material (e.g., charge-storage material), and an insulative charge-passage material. The storage material (e.g., floating gate material such as doped or undoped silicon or charge-trapping material such as silicon nitride, metal dots, etc.) of the individual memory cells may be elevationally along individual of the charge-blocking regions. The insulative charge-passage material (e.g., a band gap-engineered structure having nitrogen-containing material [e.g., silicon nitride] sandwiched between two insulator oxides [e.g., silicon dioxide]) may be laterally between the channel material and the storage material. Example channel materials 36 include appropriately-doped crystalline semiconductor material, such as one or more silicon, germanium, and so-called III/V semiconductor materials (e.g., GaAs, InP, GaP, and GaN).

The figures show one embodiment wherein charge-blocking material 30, storage material 32, and charge-passage material 34 have been formed through insulative tiers 20 and conductive tiers 22 prior to forming channel material 36 of channel-material strings 53. Materials 30, 32, 34 and 36 may be formed by, for example, deposition of respective thin layers thereof over stack 18 and within the depicted trenches followed by planarizing such back at least to a top surface of stack 18 as shown. Example thickness for each of materials 30, 32, 34, and 36 is 25 to 100 Angstroms, and such are typically thinner than tiers 20 and 22. Such is not shown in the drawings for emphasis in showing example structural attributes associated with materials 30, 32, 34, and 36. Further, the trenches in which materials 30, 32, 34, and 36 are received are shown as having vertical sidewalls although such may taper inwardly and/or outwardly moving deeper into stack 18 (not shown). Punch etching may be conducted as shown to remove materials 30, 32, and 34 at their bottoms to expose conductor tier 16 such that channel material 36 (channel-material string 53) is directly electrically coupled with conductor material 17 of conductor tier 16. Such punch etching may occur separately with respect to each of materials 30, 32, and 34 (as shown) or may occur collectively with respect to all after deposition of material 34 (not shown). Alternately, and by way of example only, no punch etching may be conducted and channel material 36 may be directly electrically coupled with conductor material 17 of conductor tier 16 by a separate conductive interconnect (not shown).

In some embodiments and as shown, first trenches 66 (e.g., formed by materials 34 and 36) extend through stack 18 and are horizontally elongated in the Y direction. Individual of first trenches 66 are in one of individual sets 60 and extend horizontally through groups 62 between channel-material strings 53 and across space 67 in the one individual set 60. In some such embodiments, sidewalls 68 of first trenches 66 comprise channel material 36 of channel-material strings 53 and blocking insulator 30, with channel material 36 and blocking insulator 30 alternating with one another along the Y direction.

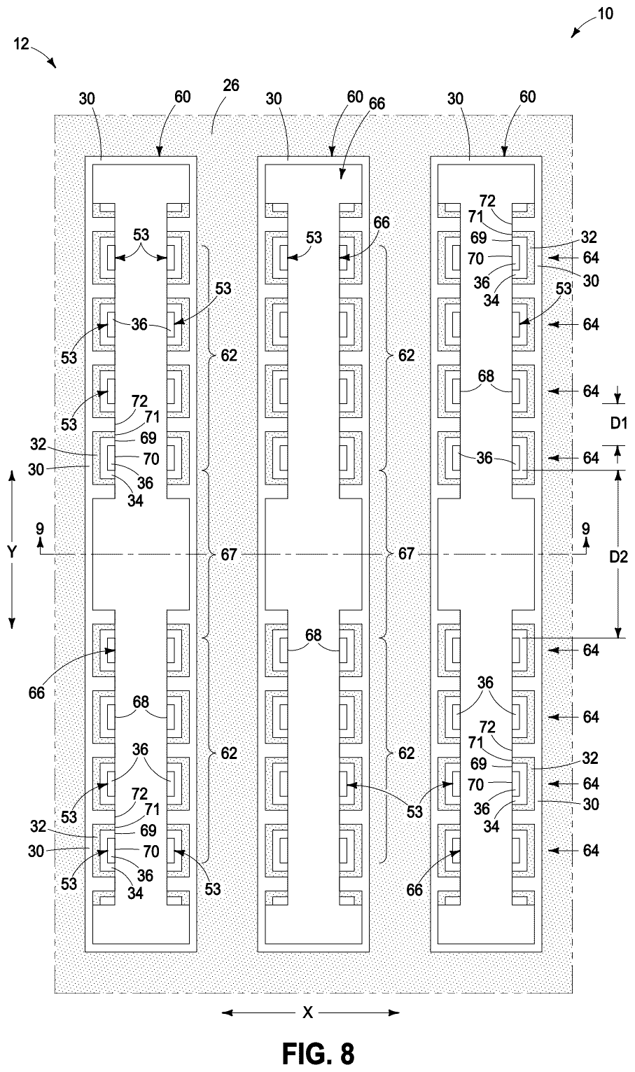

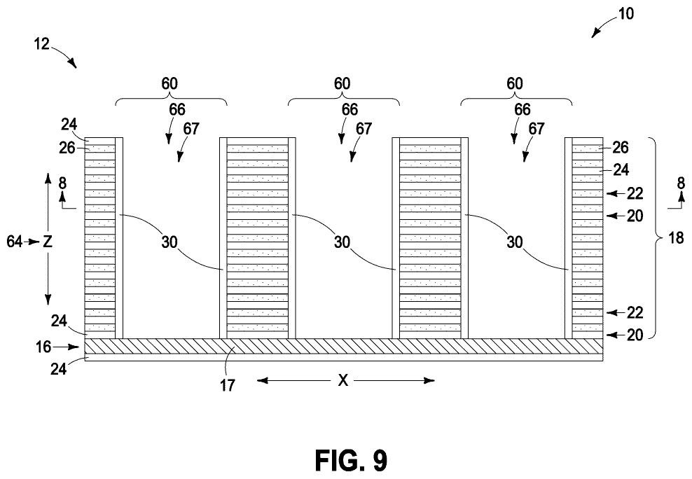

Referring to FIGS. 8 and 9, and in one embodiment, at least some of blocking insulator 30 has been removed (e.g., by timed isotropic etching) from sidewalls 68 of first trenches 66 to widen at least part of first trenches 66 in the X direction. In one such embodiment and as shown, at least some of storage material 32 has also been removed (e.g., by timed isotropic etching). In some embodiments, such removing may form one or more planar surfaces 69, 70, 71, and 72, respectively, of tunnel insulator 34, channel material 36, storage material 32, and blocking insulator 30, respectively. In some such embodiments, at least two, in some embodiments at least three, and in some embodiments all four (all four as shown), of planar surfaces 69, 70, 71, and 72 in different ones of rows 64 in different ones of groups 62 in individual sets 60 are coplanar in the Y direction. Alternately, none, only one, only two, or only three of surfaces 69, 70, 71, and 72 may be planar.

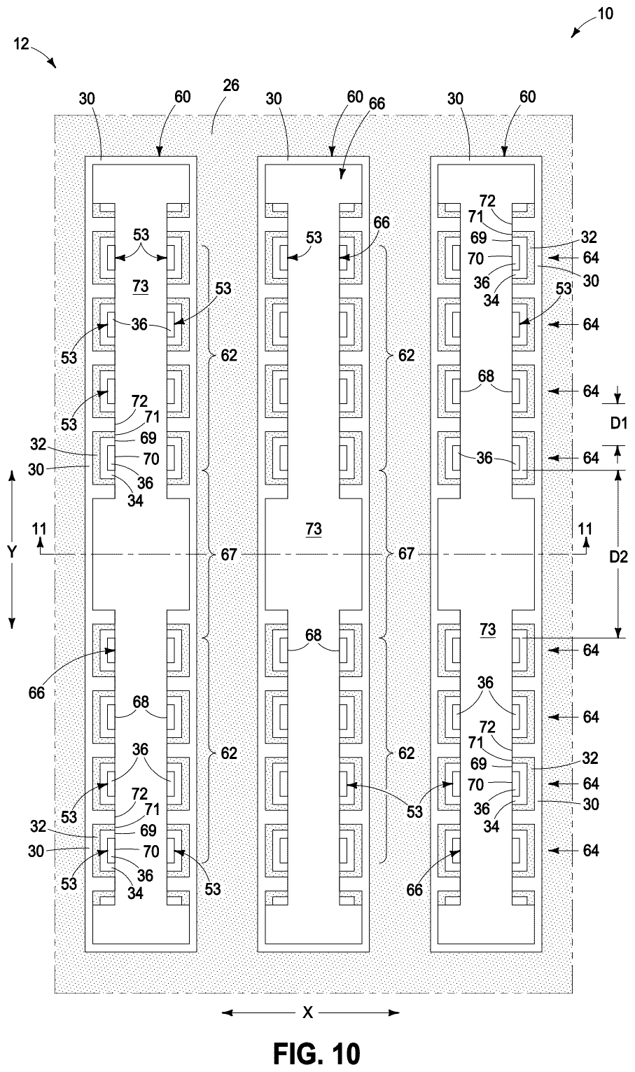

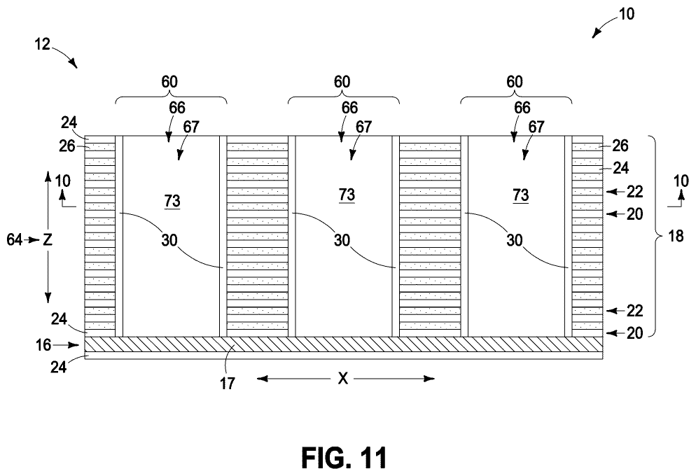

Referring to FIGS. 10 and 11, first trenches 66 have been filled with insulator material 73 (e.g., silicon dioxide).

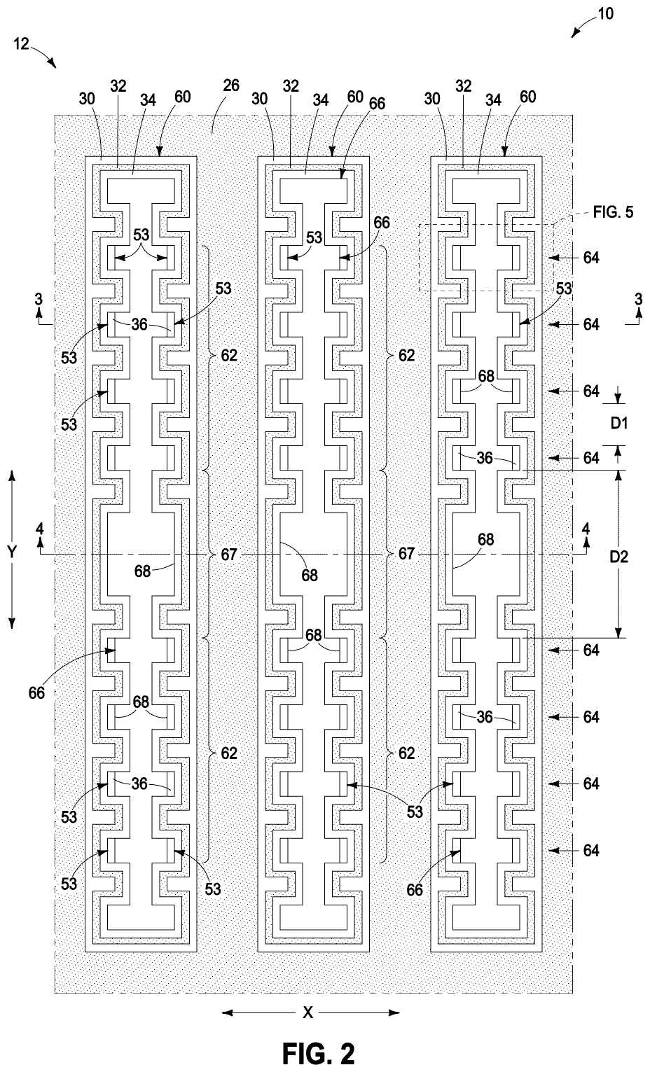

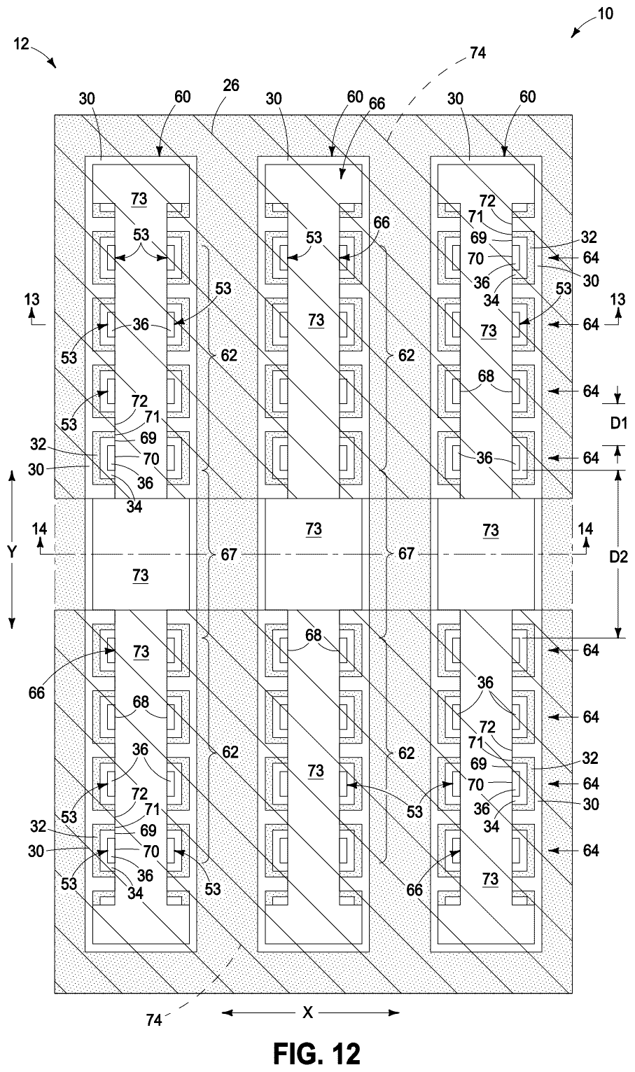

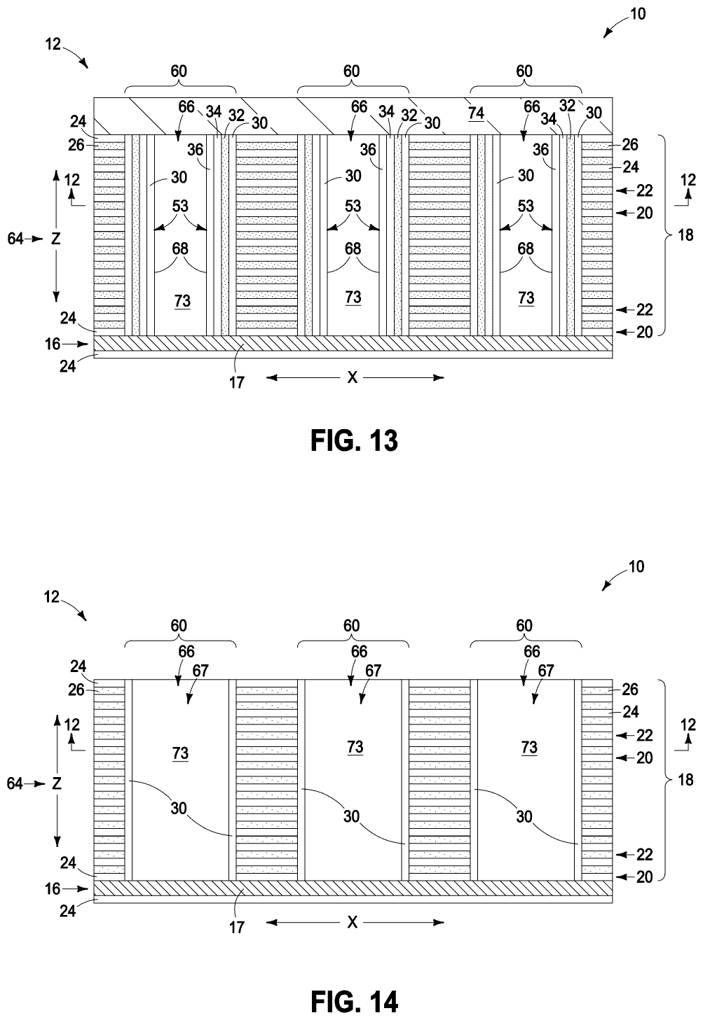

Referring to FIGS. 12-14, insulator material 73 has been masked (e.g., with sacrificial masking material 74) in individual sets 60 to leave at least some of insulator material 73 in space 67 outwardly exposed in those individual sets through which trenches will be formed as is described below. FIG. 12 is diagrammatic in showing where masking material 74 would be atop that structural outline (with hatch lines), although FIG. 12 is a horizontal cross-section taken in the midst of stack 18 as indicated by section lines 12-12 in FIGS. 13 and 14 and corresponding to such section views of FIGS. 2, 8, and 10.

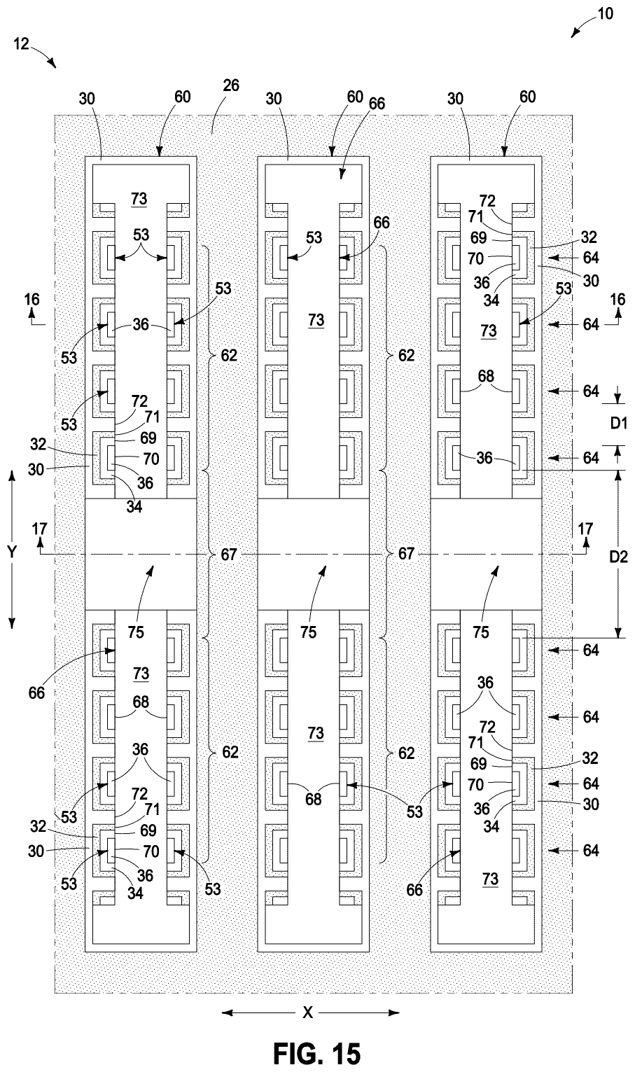

Referring to FIGS. 15-17, openings 75 have been formed through stack 18 in space 67 that is between individual groups 62 in individual sets 60, with openings 75 individually extending in the X direction to expose sacrificial material 26 to openings 75. Openings 75 are formed in those individual sets 60 horizontally through which trenches will be formed as referred to above and described below. Sacrificial masking material 74 (not shown) has been removed during and/or after forming openings 75. In one embodiment and as shown, openings 75 have been formed through outwardly-exposed insulator material 73 (when used) that is in space 67. In one such embodiment, the forming of openings 75 comprises dry etching of outwardly-exposed insulator material 73 that is in space 67. In one embodiment and as shown, such forming of openings 75 also comprises dry etching of blocking insulator 30 (at least) to expose sacrificial material 26 to openings 75. The artisan is capable of selecting various anis otropic and/or isotropic etching chemistries to achieve the depicted profile depending on compositions of materials 30, 32, 34, and 36.

The above described and shown embodiment is but one example manner of forming openings 75 through stack 18 in space 67 that is between individual groups 62 in individual sets 60 where individually openings 75 extend in the X direction to expose sacrificial material 26 to openings 75. Alternate manners may be used, with two examples of such manners being described below with respect to constructions 10a and 10b.

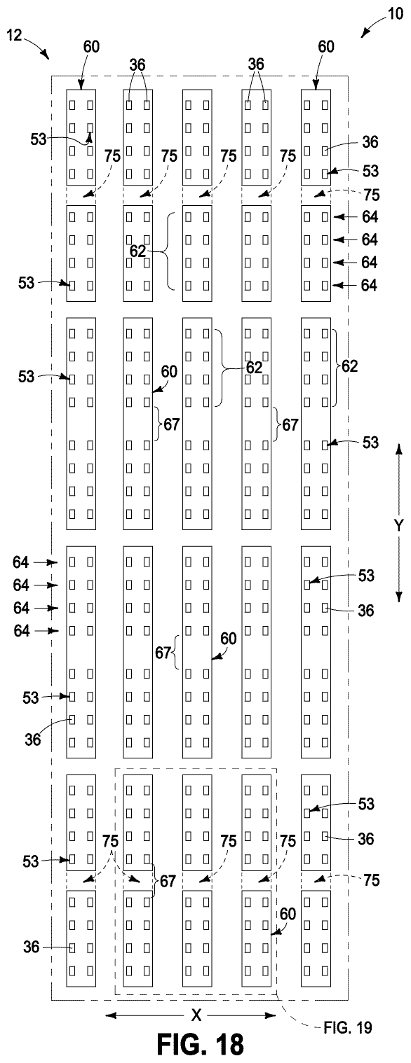

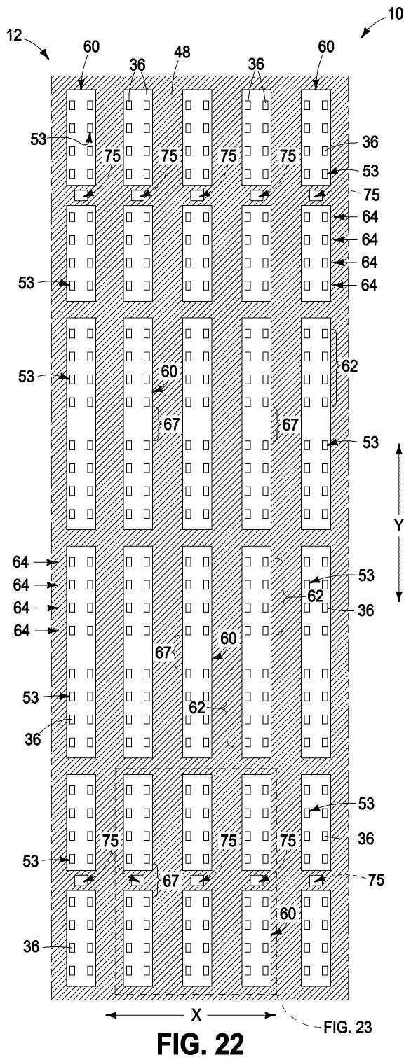

Referring to FIGS. 18-21, sacrificial material 26 (not shown) has been removed (e.g., by selective etching using H₃PO₄ if silicon nitride) from first tiers 22 through openings 75. FIGS. 22-25 show formation of conductive material 48 (conductive metal material) through openings 75 into void-space therein resulting from the removing of sacrificial material 26. Such is but one example of, through openings 75, replacing sacrificial material 26 with conductive material 48 that completely surrounds individual groups 62 and individual sets 60 in individual first tiers 22. Conductive material 48 extends along the X direction between immediately-X-direction-adjacent openings 75.

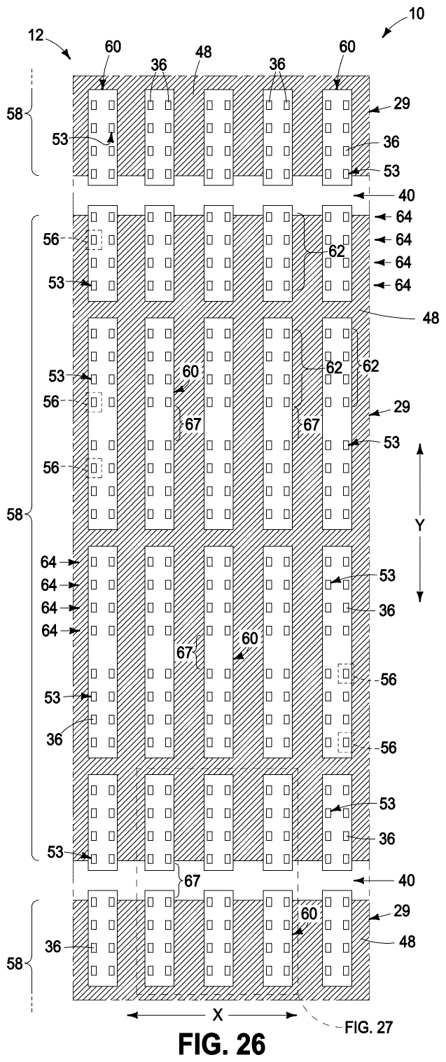

Referring to FIGS. 26-32, conductive material 48 has been removed from openings 75 (e.g., by selective etching) and removed in individual first tiers 22 sufficiently to form trenches 40, in some embodiments referred to as second trenches 40, through stack 18 and that are horizontally elongated in the X direction and form memory blocks 58 that are spaced from one another in the Y direction. Individual trenches 40 extend through multiple sets 60 and through space 67 that is between individual groups 62 in individual sets 60.

Such removing of conductive material 48 to form trenches 40 forms individual conductive lines 29 (e.g., wordlines) in stack 18 and elevationally-extending strings 49 of individual transistors and/or memory cells 56 in stack 18. After removing sacrificial materials 26 and prior to the forming conductive material 48, first tiers 22 may be lined with an insulating material (e.g., AlOₓ and not shown), with conductive material 48 being formed thereover.

Approximate locations of transistors and/or memory cells 56 are indicated with a bracket in some figures and some with dashed outlines in some figures. Conductive material 48 may be considered as having control-gate regions 52 of individual transistors and/or memory cells 56. Control-gate regions 52 in the depicted embodiment comprise individual portions of individual conductive lines 29.

A charge-blocking region (e.g., charge-blocking material 30) is between storage material 32 and individual control-gate regions 52. A charge block may have the following functions in a memory cell: In a program mode, the charge block may prevent charge carriers from passing out of the storage material (e.g., floating-gate material, charge-trapping material, etc.) toward the control gate, and in an erase mode the charge block may prevent charge carriers from flowing into the storage material from the control gate. Accordingly, a charge block may function to block charge migration between the control-gate region and the storage material of individual memory cells. An example charge-blocking region as shown comprises insulator material 30. By way of further examples, a charge-blocking region may comprise a laterally (e.g., radially) outer portion of the storage material (e.g., material 32) where such storage material is insulative (e.g., in the absence of any different-composition material between an insulative storage material 32 and conductive material 48). Regardless, as an additional example, an interface of a storage material and conductive material of a control gate may be sufficient to function as a charge-blocking region in the absence of any separate-composition-insulator material 30. Further, an interface of conductive material 48 with material 30 (when present) in combination with insulator material 30 may together function as a charge-blocking region, and as alternately or additionally may a laterally-outer region of an insulative storage material (e.g., a silicon nitride material 32). An example material 30 is one or more of silicon hafnium oxide and silicon dioxide.

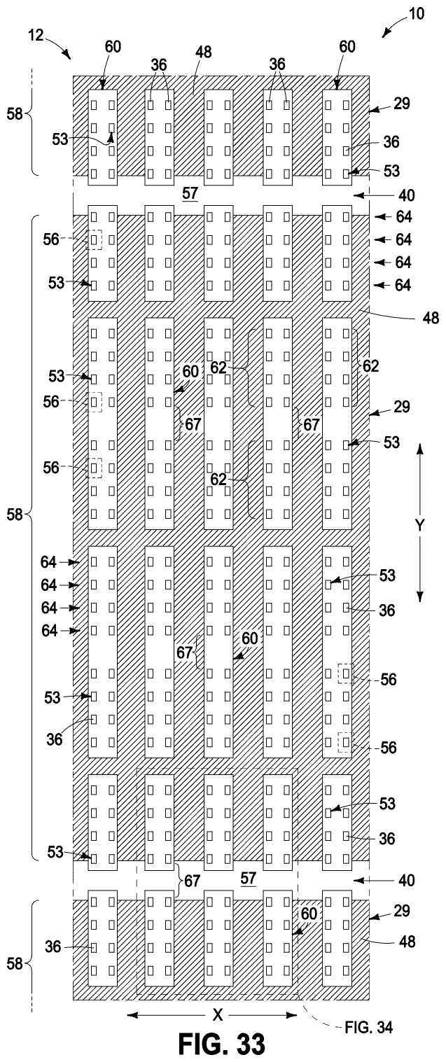

Referring to FIGS. 33-35, a wall 57 has been formed in individual trenches 40. Wall 57 may provide lateral electrical isolation (insulation) between immediately-Y-direction-adjacent memory blocks 58. Example insulative materials are one or more of SiO₂, Si₃N₄, and Al₂O₃. Wall 57 may include through-array-vias (not shown).

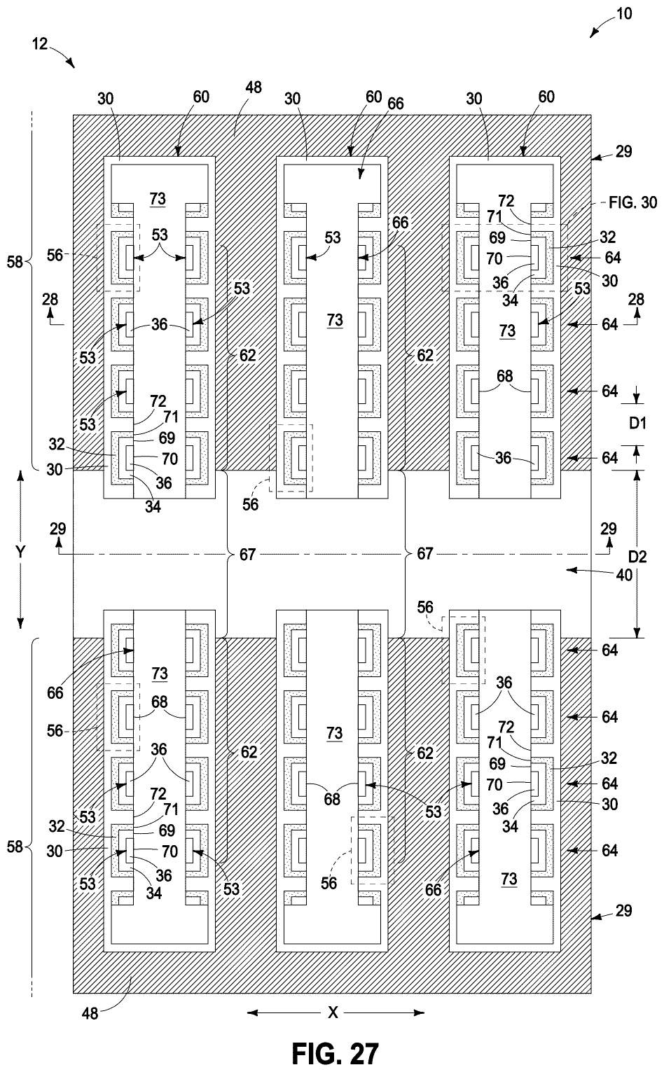

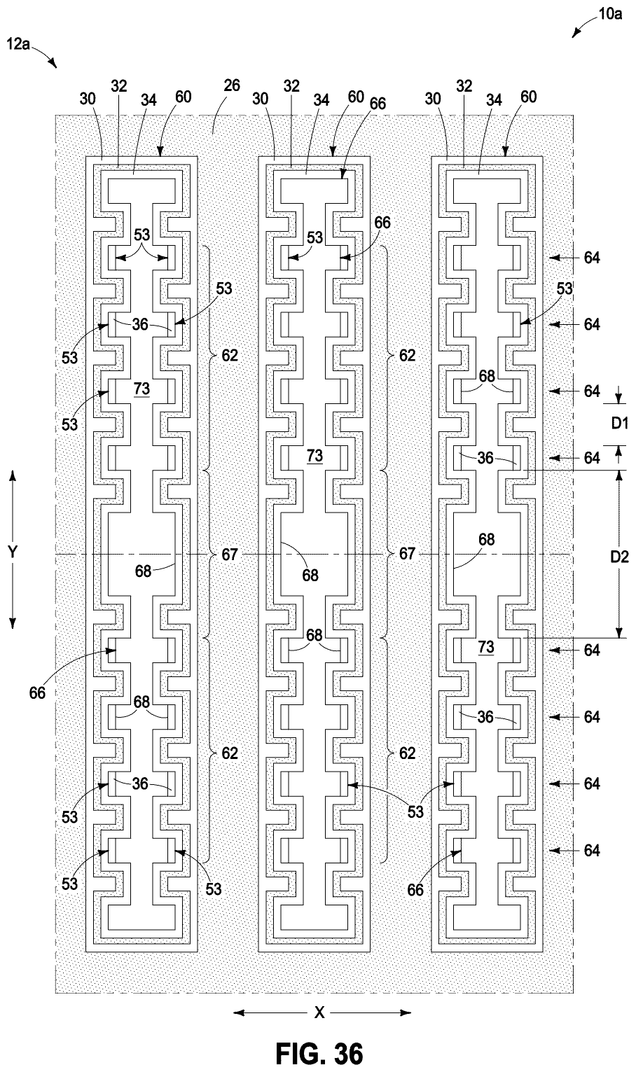

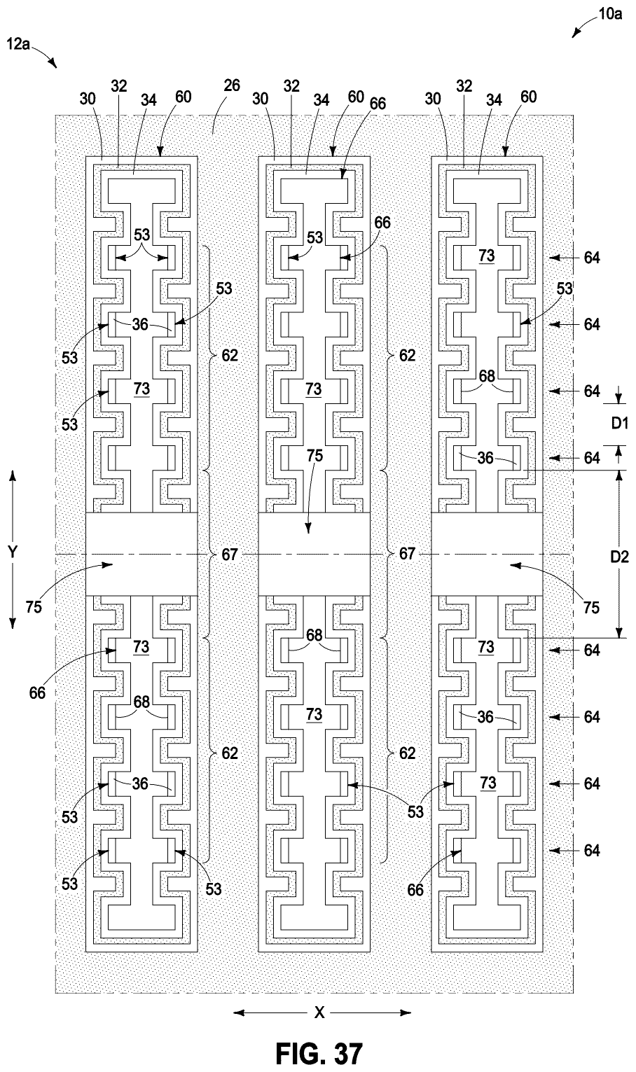

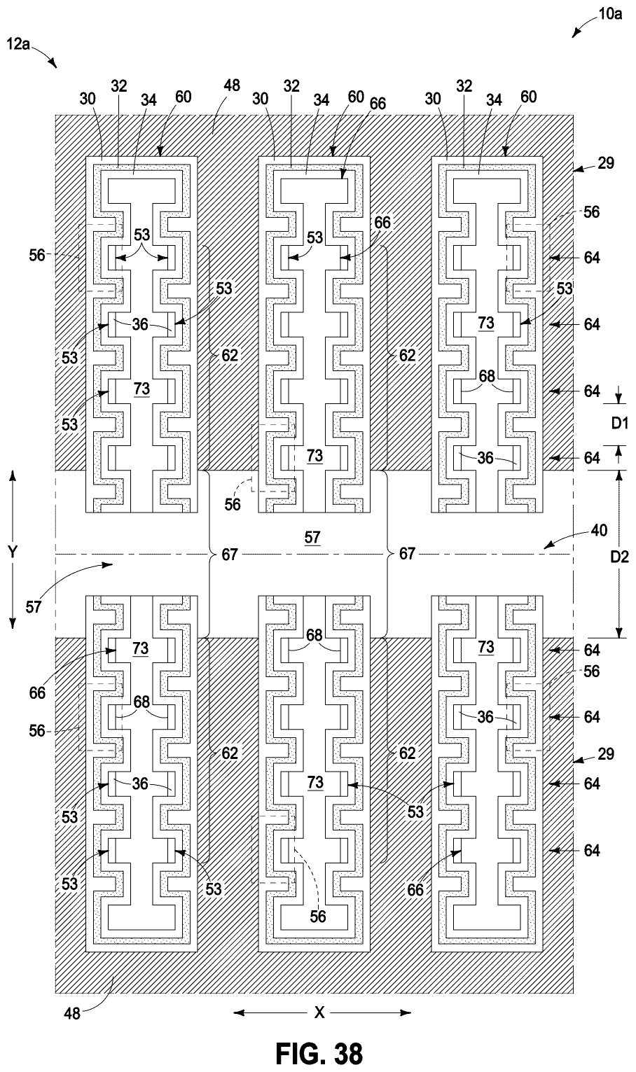

An alternate embodiment method and construction 10a comprising a memory array 12a is described with reference to FIGS. 36-38. Like numerals from the above-described embodiments have been used where appropriate, with some construction differences being indicated with the suffix “a” or with different numerals. FIG. 36 shows alternate processing to that shown by FIG. 10. As evident from FIG. 36, and in one embodiment, the processing shown by FIGS. 8 and 9 has not occurred prior to forming insulator material 73 in first trenches 66. FIG. 37 shows subsequent processing having occurred analogous to that shown by FIG. 15, with in one embodiment the forming of openings 75 comprising wet etching of outwardly-exposed insulator material 73 that is in space 67 from FIG. 36. In one such embodiment, the forming of openings 75 also comprises wet etching blocking insulator 30, wet etching storage material 32, and wet etching tunnel insulator 34 from FIG. 36 to expose sacrificial material 26 to the openings 75 as shown in FIG. 37. Again, the artisan is capable of selecting various anisotropic and/or isotropic etching chemistries to achieve the depicted profile depending on compositions of the material(s) being etched relative to other exposed material(s). FIG. 38 shows an example resultant construction 10a corresponding to construction 10 in FIG. 27.

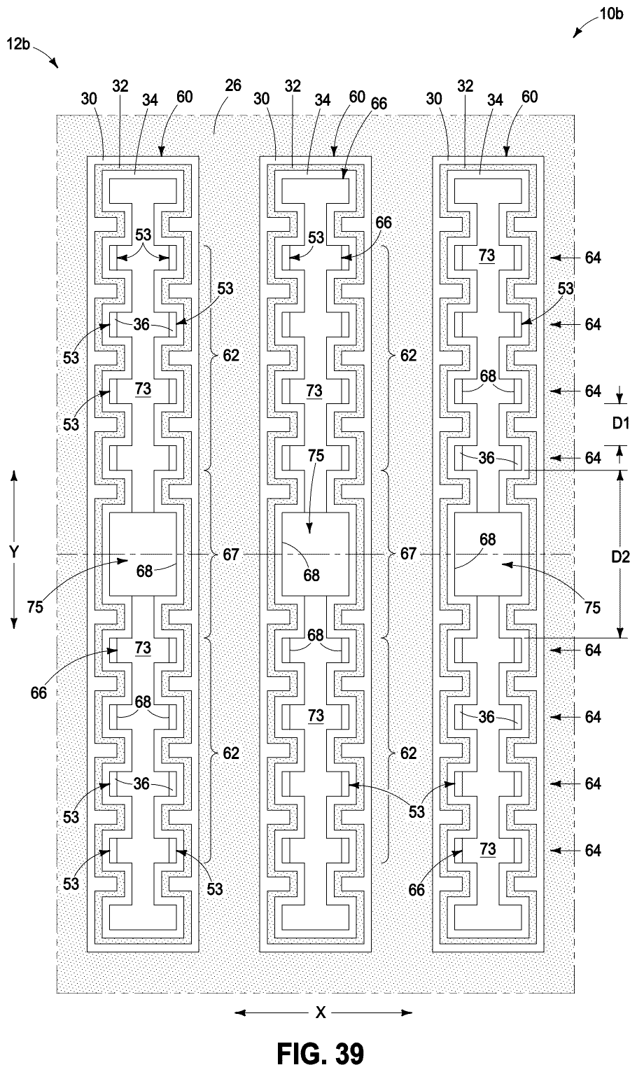

An alternate embodiment method and construction 10b comprising a memory array 12b is described with reference to FIGS. 39-41. Like numerals from the above-described embodiments have been used where appropriate, with some construction differences being indicated with the suffix “b” or with different numerals. FIG. 39 shows alternate processing to that shown by FIG. 36. At least some of space 67 in first trenches 66 has been masked (e.g., with sacrificial masking material and not shown) while leaving remainder of first trenches 66 outwardly exposed. Thereafter, as shown in FIG. 39, remainder of first trenches 66 where outwardly exposed have been filled with insulator material 73 thereby forming a radially-inner portion of openings 75 through space 67 and stack 18 (e.g., followed by removal of the sacrificial masking material).

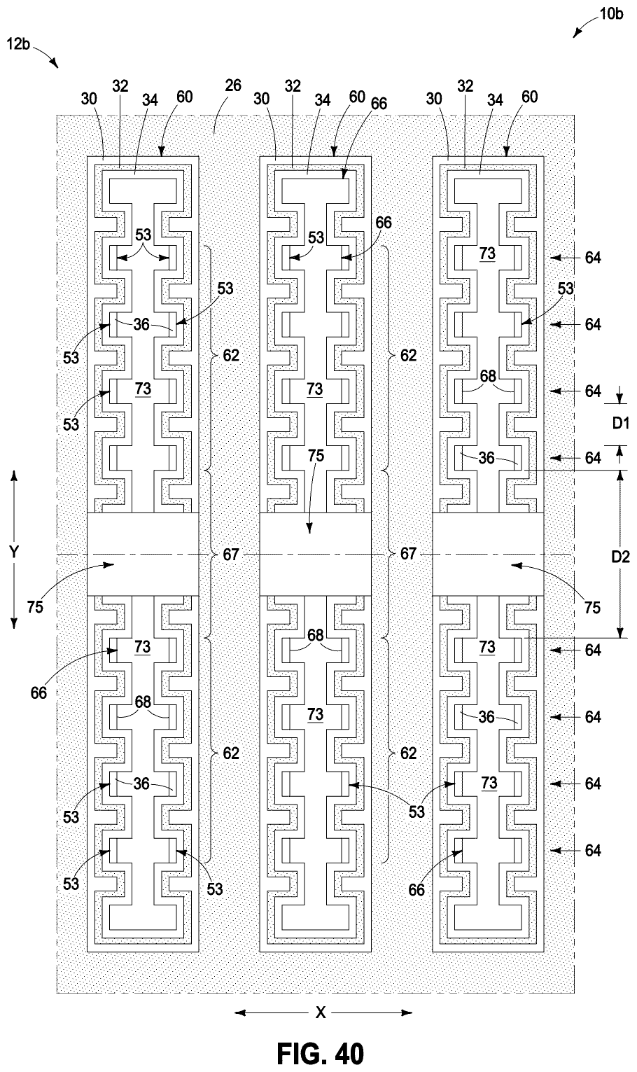

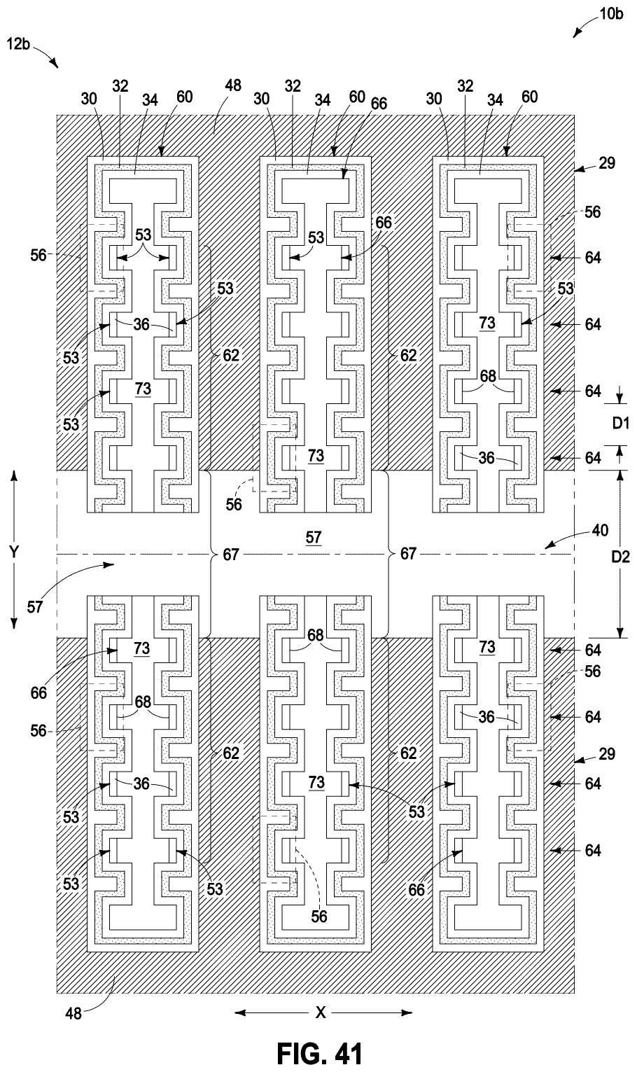

Referring to FIG. 40, and in one embodiment, etching (e.g., wet or dry) has been conducted of blocking insulator 30 (no longer shown relative to openings 75), of storage material 32 (no longer shown relative to openings 75), and of tunnel insulator 34 (no longer shown relative to openings 75) to expose sacrificial material 26 to openings 75. Some of storage material 32 may be etched in the Y direction in space 67 (not shown) during such etching. Alternately, openings 75 as shown in FIG. 39 could be initially formed as shown in FIG. 40 (not shown) towards minimizing any etching of storage material 32 in the Y direction in space 67, for example and when later etching sacrificial material 26 if such is the same composition as storage material 32. FIG. 41 shows an example resultant construction 10b corresponding to construction 10 in FIG. 27.

Any other attribute(s) or aspect(s) as shown and/or described herein with respect to other embodiments may be used in the embodiments shown and described with reference to the above embodiments.

In one embodiment, a method used in forming memory circuitry (e.g., 10, 10a, 10b) comprises forming a stack (e.g., 18) comprising vertically-alternating first tiers (e.g., 22) and second tiers (e.g., 20). The first tiers are conductive and the second tiers are insulative in a finished-circuitry construction. Channel-material strings (e.g., 53) extend through the first tiers and the second tiers. The channel-material strings are arrayed in sets (e.g., 60) that are spaced from one another in horizontal X and Y directions that are orthogonal relative one another. The channel-material strings in individual of the sets are arrayed in groups (e.g., 62) that are spaced from one another in the Y direction. Individual of the groups comprise multiple rows (e.g., 64) of the channel-material strings and that are spaced from one another in the Y direction. Y-direction distance (e.g., D2) between immediately-adjacent of the groups is greater than Y-direction distance (e.g., D1) between immediately-adjacent of the rows within the individual groups. The stack is divided into memory-block regions (e.g., 58) that are spaced from one another in the Y direction. A wall (e.g., 57) is formed between immediately-adjacent of the memory-block regions. The wall extends through the stack and is horizontally elongated in the X direction through multiple of the sets and through space that is between the individual groups in the individual sets.

In one such embodiment, the memory circuitry being formed comprises memory cells (e.g., 56) that individually comprise tunnel insulator (e.g., 34), channel material (e.g., 36) of one of the channel-material strings, storage material (e.g., 32), and blocking insulator (e.g., 30). At least two of the tunnel insulator, the channel material, the storage material, and the blocking insulator in different ones of the rows in different ones of the groups in the individual sets comprise planar surfaces (e.g., any two of 69, 70, 71, and 72) that are coplanar in the Y direction. In one such embodiment, the planar surfaces of at least three, in one embodiment all four, of the tunnel insulator, the channel material, the storage material, and the blocking insulator in the different ones of the rows in the different ones of the groups in the individual sets are coplanar in the Y direction.

Any other attribute(s) or aspect(s) as shown and/or described herein with respect to other embodiments may be used.

Alternate embodiment constructions may result from method embodiments described above, or otherwise. Regardless, embodiments of the invention encompass memory arrays independent of method of manufacture. Nevertheless, such memory arrays may have any of the attributes as described herein in method embodiments. Likewise, the above-described method embodiments may incorporate, form, and/or have any of the attributes described with respect to device embodiments.

In one embodiment, a memory array (e.g., 12, 12a, 12b) comprises a stack (e.g., 18) comprising vertically-alternating insulative tiers (e.g., 20) and conductive tiers (e.g., 22). Channel-material strings (e.g., 53) extend through the insulative tiers and the conductive tiers. The channel-material strings are arrayed in sets (e.g., 60) that are spaced from one another in horizontal X and Y directions that are orthogonal relative one another. The channel-material strings in individual of the sets are arrayed in groups (e.g., 62) that are spaced from one another in the Y direction. Individual of the groups comprise multiple rows (e.g., 64) of the channel-material strings and that are spaced from one another in the Y direction. Y-direction distance (e.g., D2) between immediately-adjacent of the groups is greater than Y-direction distance (e.g., D1) between immediately-adjacent of the rows within the individual groups. The stack comprises memory blocks (e.g., 58) that are spaced from one another in the Y direction. Immediately-adjacent of the memory blocks have a wall (e.g., 57) there-between that extends through the stack and is horizontally elongated in the X direction through multiple of the sets and through space (e.g., 67) that is between the individual groups in the individual sets.

In some embodiments, the memory array (e.g., 12) comprises memory cells (e.g., 56) that individually comprise tunnel insulator (e.g., 34), channel material (e.g., 36) of one of the channel-material strings, storage material (e.g., 32), and blocking insulator (e.g., 30). In one of such embodiments, the tunnel insulator and the storage material in different ones of the rows in different ones of the groups in the individual sets comprise planar surfaces (e.g., 69 and 71, respectively) that are coplanar in the Y direction. In one of such embodiments, the channel material and the tunnel insulator in different ones of the rows in different ones of the groups in the individual sets comprise planar surfaces (e.g., 70 and 69, respectively) that are coplanar in the Y direction. In one of such embodiments, the channel material and the storage material in different ones of the rows in different ones of the groups in the individual sets comprise planar surfaces (e.g., 70 and 71, respectively) that are coplanar in the Y direction. In one of such embodiments, the tunnel insulator, the storage material, and the blocking insulator in different ones of the rows in different ones of the groups in the individual sets comprise planar surfaces (e.g., 69, 71, and 72, respectively) that are coplanar in the Y direction. In one of such embodiments, the tunnel insulator, the channel material, the storage material, and the blocking insulator in different ones of the rows in different ones of the groups in the individual sets comprise planar surfaces (e.g., 69, 70, 71, and 72, respectively) that are coplanar in the Y direction.

Any other attribute(s) or aspect(s) as shown and/or described herein with respect to other embodiments may be used.

Constructions prior to those of the invention formed walls in trenches that were between the sets as opposed to through space that is within the sets. Circuit density increase and/or cost reduction may be achieved by embodiments of the invention.

The memory circuitry described herein (e.g., conductive vias thereof) may connect with circuitry that is on either the top or the bottom (i.e., either z-axis side) of the stack regardless of orientation of the construction in three-dimensional space and which is not material to aspects of the inventions disclosed herein. For example, and by way of example only, the conductive vias may connect with peripheral control circuitry that is beneath the stack with respect to the orientation shown in the drawings. As an alternate example, and by way of example only, the conductive vias may connect with peripheral control circuitry that is above the stack with respect to the shown orientation, for example to another substrate having such circuitry and that is bonded with the top of the stack with respect to the shown orientation. In such alternate example, the construction may be inverted from the shown orientation and then bonded with the other substrate. Further, in such alternate example, source lines or plates may be fabricated relative to the bottom of the stack with respect to the shown orientation but inverted therefrom during processing. Such source lines or plates may connect with conductive vias that extend through the stack to the substrate bonded with the other side that has such peripheral control circuitry. Regardless, constructions as shown and described herein may be processed, packaged, and/or mounted in any three-dimensional spatial orientation.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The assemblies and structures discussed above may be used in integrated circuits/circuitry and may be incorporated into electronic systems. Such electronic systems may be used in, for example, memory modules, device drivers, modems, power modules, communication processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication and as shown in drawings (if any) herein. Further, “vertical” and “horizontal” as used herein are generally perpendicular directions relative one another and independent of orientation of the substrate in three-dimensional space during fabrication and/or in a finished construction. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### CONCLUSION

In some embodiments, a method used in forming memory circuitry comprises forming a stack comprising vertically-alternating first tiers and second tiers. The first tiers are conductive and the second tiers are insulative in a finished-circuitry construction. Channel-material strings extend through the first tiers and the second tiers. The channel-material strings are arrayed in sets that are spaced from one another in horizontal X and Y directions that are orthogonal relative one another. The channel-material strings in individual of the sets are arrayed in groups that are spaced from one another in the Y direction. Individual of the groups comprise multiple rows of the channel-material strings and are spaced from one another in the Y direction. Y-direction distance between immediately-adjacent of the groups is greater than Y-direction distance between immediately-adjacent of the rows within the individual groups. The stack is divided into memory-block regions that are spaced from one another in the Y direction. A wall is formed between immediately-adjacent of the memory-block regions. The wall extends through the stack and is horizontally elongated in the X direction through multiple of the sets and through space that is between the individual groups in the individual sets.

In some embodiments, a method used in forming memory circuitry comprises forming a stack comprising vertically-alternating first tiers and second tiers. The first tiers comprise sacrificial material and the second tiers comprise insulative material that is of different composition from that of the sacrificial material. Channel-material strings extend through the first tiers and the second tiers. The channel-material strings are arrayed in sets that are spaced from one another in horizontal X and Y directions that are orthogonal relative one another. The channel-material strings in individual of the sets are arrayed in groups that are spaced from one another in the Y direction. Individual of the groups comprise multiple rows of the channel-material strings and are spaced from one another in the Y direction. Y-direction distance between immediately-adjacent of the groups is greater than Y-direction distance between immediately-adjacent of the rows within the individual groups. Openings are formed through the stack in space that is between the individual groups in the individual sets. The openings individually extend in the X direction to expose the sacrificial material to the openings. The openings are formed in those of the individual sets horizontally through which trenches will be formed. Through the openings, the sacrificial material is replaced with conductive material that completely surrounds the individual groups and the individual sets in individual of the first tiers. The conductive material extends along the X direction between immediately-X-direction-adjacent of the openings. The conductive material is removed from the openings and in the individual first tiers sufficiently to form the trenches through the stack that are horizontally elongated in the X direction and form memory blocks that are spaced from one another in the Y direction. Individual of the trenches extend through multiple of the sets and through the space that is between the individual groups in the individual sets. A wall is formed in the individual trenches.

In some embodiments, a memory array comprises a stack comprising vertically-alternating insulative tiers and conductive tiers. Channel-material strings extend through the insulative tiers and the conductive tiers. The channel-material strings are arrayed in sets that are spaced from one another in horizontal X and Y directions that are orthogonal relative one another. The channel-material strings in individual of the sets are arrayed in groups that are spaced from one another in the Y direction. Individual of the groups comprise multiple rows of the channel-material strings and that are spaced from one another in the Y direction. Y-direction distance between immediately-adjacent of the groups is greater than Y-direction distance between immediately-adjacent of the rows within the individual groups. The stack comprises memory blocks that are spaced from one another in the Y direction. Immediately-adjacent of the memory blocks have a wall there-between that extends through the stack and is horizontally elongated in the X direction through multiple of the sets and through space that is between the individual groups in the individual sets.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method used in forming memory circuitry, comprising:
forming a stack comprising vertically-alternating first tiers and second tiers, the first tiers being conductive and the second tiers being insulative in a finished-circuitry construction, channel-material strings extending through the first tiers and the second tiers, the channel-material strings being arrayed in sets that are spaced from one another in horizontal X and Y directions that are orthogonal relative one another, the channel-material strings in individual of the sets being arrayed in groups that are spaced from one another in the Y direction, individual of the groups comprising multiple rows of the channel-material strings and that are spaced from one another in the Y direction, Y-direction distance between immediately-adjacent of the groups being greater than Y-direction distance between immediately-adjacent of the rows within the individual groups;
dividing the stack into memory-block regions that are spaced from one another in the Y direction; and
forming a wall between immediately-adjacent of the memory-block regions, the wall extending through the stack and being horizontally elongated in the X direction through multiple of the sets and through space that is between the individual groups in the individual sets.

2. The method of claim 1 wherein the memory circuitry being formed comprises memory cells that individually comprise tunnel insulator, channel material of one of the channel-material strings, storage material, and blocking insulator; at least two of the tunnel insulator, the channel material, the storage material, and the blocking insulator in different ones of the rows in different ones of the groups in the individual sets comprising planar surfaces that are coplanar in the Y direction.

3. The method of claim 2 wherein the planar surfaces of at least three of the tunnel insulator, the channel material, the storage material, and the blocking insulator in the different ones of the rows in the different ones of the groups in the individual sets are coplanar in the Y direction.

4. The method of claim 2 wherein the planar surfaces of all four of the tunnel insulator, the channel material, the storage material, and the blocking insulator in the different ones of the rows in the different ones of the groups in the individual sets are coplanar in the Y direction.

5. A method used in forming memory circuitry, comprising:
forming a stack comprising vertically-alternating first tiers and second tiers, the first tiers comprising sacrificial material and the second tiers comprising insulative material that is of different composition from that of the sacrificial material, channel-material strings extending through the first tiers and the second tiers, the channel-material strings being arrayed in sets that are spaced from one another in horizontal X and Y directions that are orthogonal relative one another, the channel-material strings in individual of the sets being arrayed in groups that are spaced from one another in the Y direction, individual of the groups comprising multiple rows of the channel-material strings and that are spaced from one another in the Y direction, Y-direction distance between immediately-adjacent of the groups being greater than Y-direction distance between immediately-adjacent of the rows within the individual groups;
forming openings through the stack in space that is between the individual groups in the individual sets, the openings individually extending in the X direction to expose the sacrificial material to the openings, the openings being formed in those of the individual sets horizontally through which trenches will be formed;
through the openings, replacing the sacrificial material with conductive material that completely surrounds the individual groups and the individual sets in individual of the first tiers; the conductive material extending along the X direction between immediately-X-direction-adjacent of the openings;
removing the conductive material from the openings and in the individual first tiers sufficiently to form the trenches through the stack that are horizontally elongated in the X direction and form memory blocks that are spaced from one another in the Y direction, individual of the trenches extending through multiple of the sets and through the space that is between the individual groups in the individual sets; and
forming a wall in the individual trenches.

6. The method of claim 5 wherein the trenches are second trenches, and further comprising:
first trenches extending through the stack and that are horizontally elongated in the Y direction, individual of the first trenches being in one of the individual sets and extending horizontally through the groups between the channel-material strings and across the space in the one individual set;
filling the first trenches with insulator material;
masking the insulator material in the individual sets to leave at least some of the insulator material in the space outwardly exposed; and
forming the openings through the outwardly-exposed insulator material that is in the space.

7. The method of claim 6 wherein sidewalls of the first trenches comprise channel material of the channel-material strings and blocking insulator of memory cells of the memory circuitry being formed, the channel material and the blocking insulator alternating with one another along the Y direction, and further comprising:
removing at least some of the blocking insulator from the sidewalls of the first trenches to widen at least part of the first trenches in the X direction before the filling of the first trenches with the insulator material; and
the forming of the openings comprising dry etching of the outwardly-exposed insulator material that is in the space.

8. The method of claim 7 wherein the forming of the openings comprises dry etching the blocking insulator to expose the sacrificial material to the openings.

9. The method of claim 6 wherein sidewalls of the first trenches comprise channel material of the channel-material strings and blocking insulator of memory cells of the memory circuitry being formed, the channel material and the blocking insulator alternating with one another along the Y direction; and
the forming of the openings comprising wet etching of the outwardly-exposed insulator material that is in the space.

10. The method of claim 9 wherein the forming of the openings comprises wet etching blocking insulator of the memory cells of the memory circuitry being formed, wet etching storage material of the memory cells of the memory circuitry being formed, and wet etching tunnel insulator of the memory cells of the memory circuitry being formed to expose the sacrificial material to the openings.

11. The method of claim 5 wherein the trenches are second trenches, and further comprising:
first trenches extending through the stack and that are horizontally elongated in the Y direction, individual of the first trenches being in one of the individual sets and extending horizontally through the groups between the channel-material strings and across the space in the one individual set;
masking at least some of the space in the first trenches while leaving remainder of the first trenches outwardly exposed; and
filling the remainder of the first trenches where outwardly exposed with insulator material thereby forming a radially-inner portion of the openings through the space and stack.

12. The method of claim 11 wherein, after forming the radially-inner portion of the openings, wet etching blocking insulator of memory cells of the memory circuitry being formed, wet etching storage material of the memory cells of the memory circuitry being formed, and wet etching tunnel insulator of the memory cells of the memory circuitry being formed to expose the sacrificial material to the openings.

13. A memory array comprising:
a stack comprising vertically-alternating insulative tiers and conductive tiers;
channel-material strings extending through the insulative tiers and the conductive tiers, the channel-material strings being arrayed in sets that are spaced from one another in horizontal X and Y directions that are orthogonal relative one another, the channel-material strings in individual of the sets being arrayed in groups that are spaced from one another in the Y direction, individual of the groups comprising multiple rows of the channel-material strings and that are spaced from one another in the Y direction, Y-direction distance between immediately-adjacent of the groups being greater than Y-direction distance between immediately-adjacent of the rows within the individual groups; and
the stack comprising memory blocks that are spaced from one another in the Y direction, immediately-adjacent of the memory blocks having a wall there-between that extends through the stack and is horizontally elongated in the X direction through multiple of the sets and through space that is between the individual groups in the individual sets.

14. The memory array of claim 13 wherein the rows individually have two and only two of the channel-material strings.

15. The memory array of claim 13 wherein there are two and only two groups in the individual sets.

16. The memory array of claim 13 wherein,
the rows individually have two and only two of the channel-material strings; and
there are two and only two groups in the individual sets.

17. The memory array of claim 13 wherein the memory array comprises memory cells that individually comprise tunnel insulator, channel material of one of the channel-material strings, storage material, and blocking insulator; the tunnel insulator and the storage material in different ones of the rows in different ones of the groups in the individual sets comprising planar surfaces that are coplanar in the Y direction.

18. The memory array of claim 13 wherein the memory array comprises memory cells that individually comprise tunnel insulator, channel material of one of the channel-material strings, storage material, and blocking insulator; the channel material and the tunnel insulator in different ones of the rows in different ones of the groups in the individual sets comprising planar surfaces that are coplanar in the Y direction.

19. The memory array of claim 13 wherein the memory array comprises memory cells that individually comprise tunnel insulator, channel material of one of the channel-material strings, storage material, and blocking insulator; the channel material and the storage material in different ones of the rows in different ones of the groups in the individual sets comprising planar surfaces that are coplanar in the Y direction.

20. The memory array of claim 13 wherein the memory array comprises memory cells that individually comprise tunnel insulator, channel material of one of the channel-material strings, storage material, and blocking insulator; the tunnel insulator, the storage material, and the blocking insulator in different ones of the rows in different ones of the groups in the individual sets comprising planar surfaces that are coplanar in the Y direction.

21. The memory array of claim 13 wherein the memory array comprises memory cells that individually comprise tunnel insulator, channel material of one of the channel-material strings, storage material, and blocking insulator; the tunnel insulator, the channel material, the storage material, and the blocking insulator in different ones of the rows in different ones of the groups in the individual sets comprising planar surfaces that are coplanar in the Y direction.
